(19) United States
(12) Patent Application Publication
(10) Pub. No.: US 2022/0394884 A1
(43) Pub. Date: Dec. 8, 2022

(54) COMPUTING SYSTEM CHASSIS DESIGN FOR NOISE ISOLATION AND THERMAL AIRFLOW

(71) Applicant: Intel Corporation, Santa Clara, CA (US)

(72) Inventors: Kwan Ho Lee, San Jose, CA (US); Dong-Ho Han, Beaverton, OR (US); Jose Luis Trigueros Soto, San Ramon (CR); Sean Lawrence Molloy, Hillsboro, OR (US); Tae Young Yang, Portland, OR (US); Seong-Youp Suh, Portland, OR (US); Vinay Ramachandra Gowda, Portland, OR (US)

(73) Assignee: Intel Corporation, Santa Clara, CA (US)

(21) Appl. No.: 17/890,310

(22) Filed: Aug. 18, 2022

(51) Int. Cl. H05K 7/20; H05K 9/00; H01Q 1/22

(52) U.S. Cl. CPC H05K 7/20554; H05K 7/20136; H05K 9/0081; H01Q 1/2266

(57) ABSTRACT

In some embodiments, a computer system chassis comprises a chassis side having an antenna portion and a fan portion. The antenna portion is located closer to an antenna located on an external surface of the chassis side than the fan portion. The antenna and fan portions comprise ventilation holes that provide for the venting of heated air from the chassis interior to the surrounding environment. In some embodiments, the ventilation holes in the antenna portion are thicker than the ventilation holes in the fan portion. The thicker ventilation holes provide an adequate level of EMI shielding for the antenna from platform noise generated by components (CPUs, GPUs, memories, etc.) located in the chassis interior. In other embodiments, the antenna portion comprises alternating positive and negative cross pattern ventilation holes and provides an adequate level of EMI shielding with the antenna portion ventilation holes having the same thickness as the fan portion ventilation holes.

### BACKGROUND

The chassis of a computing device, such as a desktop computer, can shield antennas located on an external surface of the chassis from electromagnetic noise generated by computer system components internal to the chassis (e.g., CPUs, GPUs, memories). A computing device chassis can also comprise openings or gaps to vent air heated air from the chassis interior to the surrounding environment.

### BRIEF DESCRIPTION OF THE DRAWINGS

FIGS. 1A, 1B, and 1C illustrate front, side, and exploded side views, respectively, of a first example chassis side.

FIGS. 2A-2C illustrate example ventilation hole patterns.

FIGS. 3A-3B illustrate first example cross pattern ventilation holes.

FIG. 4 is a chart illustrating EMI shielding dependency on ventilation hole thickness for a circular ventilation hole array.

FIGS. 5A-5B illustrate second example cross pattern ventilation holes.

FIG. 6 is a chart illustrating EMI shielding dependency on the ventilation hole patterns of FIGS. 3A-3B and FIGS. 5A-5B.

FIGS. 7A and 7B illustrate front and side views, respectively, of a second example chassis side.

FIGS. 8A-8D illustrate additional example ventilation hole patterns that can be used in an antenna portion of a chassis side.

FIG. 9 is a block diagram of an example computing system in which technologies described herein may be implemented.

### DETAILED DESCRIPTION

Modern computing devices, such as desktop computers, require a fast and reliable Internet connection, and the use of Wi-Fi technology to enable Internet connections is pervasive. Wi-Fi attach rates were over 85% in 2021 and some existing central processing units (CPUs) comprise dedicated Wi-Fi input/output (I/O) and logic interface modules (such as the CNVi (“Connectivity Integration”) Wi-Fi connectivity interface in some Intel® processors). In some existing high-performance computers (HPCs), which typically have a desktop or tower form factor, the Wi-Fi antenna is implemented with a low-profile stamped metal antenna mounted on an external surface of a front or rear side of a metal chassis. The chassis side on which the antenna is mounted is typically covered by an aesthetic plastic cover. Some existing desktop computers use a similar approach as desktop manufacturers move away from non-aesthetic solutions for Wi-Fi implementations, such as bulky external antennas, add-in-cards (AICs), dongles, and long extension coaxial cables.

Desktop computing systems are typically very cost sensitive. Encapsulation of a desktop computing platform with a metal chassis is often the most cost-effective electromagnetic interference (EMI) shielding solution and desktop motherboard designs can have as few as 4-6 layers of Type-3 printed circuit boards to keep costs down (in comparison, mobile device printed circuit boards can have up to 10-12 layers). The low number of printed circuit board layers can result in high-speed signals and power planes being exposed on the surface layer on the printed circuit board, which can result in a high level of radiated platform noise. In addition, some existing desktop computing systems use unshielded add-in-cards, interconnect cable assembles, and DDR (double data rate) UDIMM (unbuffered dual inline memory modules), which can also act as sources of radiated platform noise.

Two functions that a computing system chassis may be designed to perform are adequately shielding an antenna from electromagnetic interference (EMI) produced by components located within the chassis (such as integrated circuit components (e.g., CPUs, GPUs, memories)) and venting heated air from within the chassis to the surrounding environment to keep the chassis interior cool. These functions can place competing constraints on ventilation hole design. To pass electromagnetic compatibility (EMC) regulatory certification testing for an integrated Wi-Fi antenna (such as a Wi-Fi antenna located on an external face of a metal chassis) and to deliver high-end mobile internet or gaming user experiences, a metal chassis with fewer openings and gaps is desirable, but chassis of modern HPCs and high-end gaming PCs should have ventilation hole densities greater than those of older generation computing systems to stay adequately cooled. Simply reducing the ventilation hole density (as determined by the size and number of the ventilation holes) to achieve a desired level of EMI shielding may not provide adequate ventilation for desktop computing systems operating at high power consumption levels. Insufficient cooling can cause computing system performance issues and/or failures. Conversely, increasing the ventilation hole density to provide sufficient cooling can cause inadequate EMI shielding effectiveness, which can result in an unreliable Internet connection. EMI shielding effectiveness for a Wi-Fi antenna can be of particular importance in computing systems where system components operate within or close to a Wi-Fi frequency band. For example, systems employing Wi-Fi 6E technology, which operates in the 5.925-7.125 GHz frequency band (the 6 GHz Wi-Fi band) can be susceptible to platform noise generated by DDR5/LPDDR5 (low power DDR5) memories, which operate at a speed of 4-7 GT/s (Gigatransfers/sec).

Disclosed herein are computing system metal chassis designs that provide improved EMI shielding for Wi-Fi antennas located on an external surface of a chassis while also providing sufficient venting of heated air from within the chassis interior. Simulation results indicate that the disclosed metal chassis can provide at least 10 dB higher EMI shielding effectiveness by increasing ventilation hole thickness or incorporating alternating positive and negative cross pattern ventilation holes in a portion of the chassis near the antenna. The disclosed metal chassis can be used with various types of computing system types (gaming PCs, workstations, high-performance computing systems, etc.) and form factors (desktop, tower, rack-mounted systems, etc.). The increased EMI shielding effectiveness provided by the metal chassis designs disclosed herein can help enable computing systems that have increased platform noise shielding requirements as processor core counts and CPU/GPU (graphics processing unit) performance continues to increase year after year. Further, the metal chassis disclosed herein can be made using existing chassis manufacturing processes and tooling. Thus, an end customer may see no or minimal additional cost to a computing device incorporating a metal chassis as disclosed herein as they would comprise an existing chassis side with added ventilation brackets or ventilation hole patterns that provide a desired level of EMI shielding effectiveness. The ventilation brackets can be implemented using a modular approach, with a desired amount of EMI shielding implemented in a system through attachment of an appropriate number of ventilation brackets to a chassis side. Moreover, this solution is scalable as it can provide a desired level of EMI shielding effectiveness for Wi-Fi 6E and future higher DDR and I/O speeds.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, patterns, areas, orientations, spacings, or positions that vary slightly from the meaning of the unmodified term. For example, a first ventilation hole area that is substantially similar to a second ventilation hole area includes first ventilation hole areas that are within 10% of the second ventilation hole area. Moreover, values modified by the word “about” include values within +/−10% of the described values, and values listed as being within a range include those within a range from 10% less than the described lower range limit and 10% greater than the described higher range limit.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, an outer-most ventilation bracket in a stack of ventilation brackets attached to a unitary component of a chassis wall is located on the chassis wall (with one or more other ventilation brackets between the outer-most ventilation bracket and the chassis wall).

As used herein, the term “adjacent” refers to layers or components that are in physical contact with each other. That is, there is no layer or component between the stated adjacent layers or components. For example, adjacent ventilation holes have only a ventilation hole divider between them.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, GPU, accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

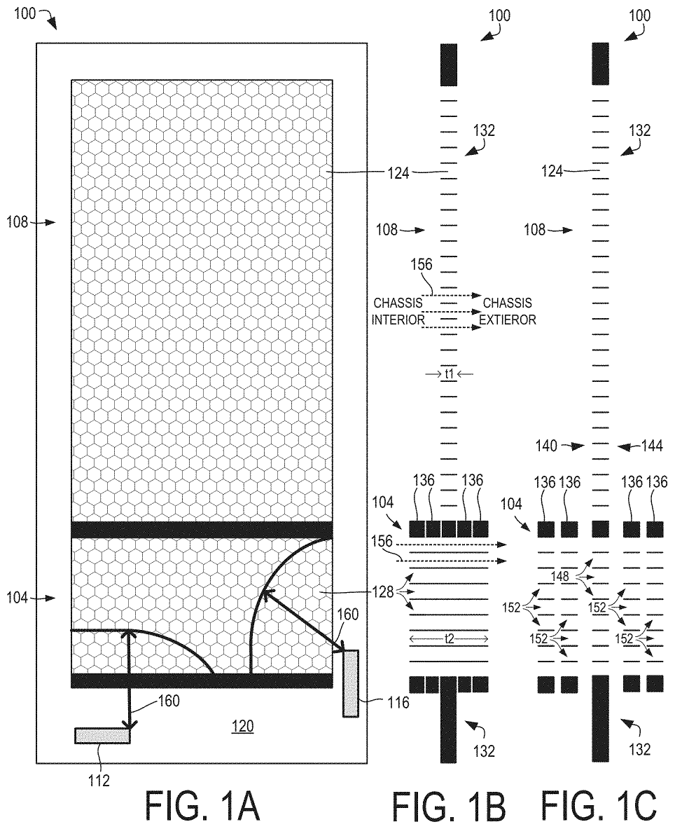

FIGS. 1A, 1B, and 1C illustrate front, side, and exploded side views, respectively, of a first example chassis side. The chassis side 100, as well as any chassis side described herein, can be part of (e.g., be a front or rear chassis side) of a chassis of any type of computing system described or referenced herein. Chassis side 100 comprises a unitary component 132 and a pair of stacked ventilation brackets 136 attached to an internal surface 140 of the unitary component 132 and a pair of stacked ventilation brackets 136 attached to an exterior surface 144 of the unitary component 132. An antenna portion 104 of the chassis side 100 comprises a first portion of the unitary component 132 and a fan portion 108 comprises a second portion of the unitary component 132. Antennas 112 and 116 are located on an external surface 120 of the chassis side 100. The fan portion 108 comprises ventilation holes 124 and the antenna portion 104 comprises ventilation holes 128. The antenna portion 104 is located closer to the antennas 112 and 116 than the fan portion 108. The unitary component 132 is a single piece of material (e.g., metal) in which the ventilation holes are formed. Heated air is vented from the chassis interior to the chassis exterior through the ventilation holes 124 and 128 in the direction indicated by arrows 156. In other embodiments, instead of a unitary component, a chassis side can comprise one or more pieces that have been joined (e.g., soldered or otherwise mechanically attached). In some of these embodiments, one or more first pieces of the chassis side can comprise the fan portion and one or more second pieces of the chassis side can comprise the antenna portion. The computing system can comprise a fan or other air mover that causes heated air to be vented through the ventilation holes 124 and 128.

The antenna portion 104 has thicker ventilation holes (made possible by attachment of the ventilation brackets 136 to the unitary component 132) than the fan portion 108 to provide adequate EMI shielding for the antennas 112 and 116. The antenna portion 104 of the chassis side 100 can extend from an antenna to a distance (e.g., distance 160 from antennas 112 and 116) at which the reception power is a threshold amount lower (e.g., 30 dB) than at the antenna. Based on simulation results, the radiated near fields of a Wi-Fi antenna used in some existing computing systems and located on the external surface of a chassis side are similar for ventilation holes with circular, hexagonal, or square shapes. The simulation results suggest that ventilation holes within 5 cm of the antenna are important for platform noise rejection for the 2.4 and 6 GHz Wi-Fi frequency bands. Thus, in some embodiments, the antenna portion of a chassis side extends at least 5 cm from the antenna. By limiting the use of thicker ventilation holes to a portion of the chassis side proximate to an antenna, the increase in chassis weight and cost due to increased ventilation hole thickness is less than if ventilation hole thicknesses were increased throughout the chassis side.

The unitary component 132 comprises ventilation holes 148 in the antenna portion 104 and ventilation brackets 136 comprise ventilation holes 152. The ventilation holes 148 and 152 are substantially similar in shape and arranged in a similar pattern. The ventilation brackets 136 are mounted to the unitary component 132 such that the ventilation holes 152 are aligned with the ventilation holes 148 in the x- and y-directions. Ventilation holes 128 are formed when the ventilation brackets 136 are attached to the unitary component 132 and extend through the unitary component 132 and the ventilation brackets 136. Simulation results suggest that increasing the thickness of the ventilation holes 128 in the antenna portion 104 from 1 mm to 3 mm through the attachment of one or more ventilation brackets 136 to the unitary component 132 does not impact the flow of heated air through the ventilation holes.

The ventilation holes 124 (and unitary component 132) have a thickness t1 in the fan portion 108 and the ventilation holes 128 have a thickness t2. The thickness t2 is equal to t1 plus the thickness of ventilation brackets 136 added to the unitary component 132. If the width of a ventilation bracket is t3, then t2=t1+n*t3, where n is the number of ventilation brackets 136 attached to the unitary component 132. In some embodiments, t1 and t3 are about 1 mm, and one or two ventilation brackets are attached to both the internal surface 140 and external surface 144 of the unitary component 132 (n=2, 4). Thus, in these embodiments, t1 is 3 mm (n=2) or 5 mm (n=4). Although two ventilation brackets 126 are shown attached to the internal and external surfaces 140 and 144, in other embodiments, more than two ventilation brackets can be attached to the internal or external surface of the unitary component 132. In some embodiments, one or more ventilation brackets can be attached to just the internal surface or just the external surface of a chassis side. In other embodiments, an uneven number of ventilation brackets are attached to the internal and external surfaces of a chassis side. For example, one ventilation bracket 136 can be attached to the internal surface and two ventilation brackets can be attached to the external surface. In still other embodiments, the antenna portion and the fan portion can be formed as a unitary component. That is, no ventilation brackets are used to create thicker ventilation holes in the antenna portion and the unitary component simply comprises thicker ventilation holes in the antenna portion and thinner ventilation holes in the fan portion.

The antennas described or referenced herein (e.g., 112 and 116) are to transmit electromagnetic waves at one or more frequencies. In some embodiments, an antenna is to transmit electromagnetic waves having a frequency of less than 10 GHz. In other embodiments, an antenna is to transmit electromagnetic waves in a Wi-Fi frequency band (e.g., a frequency band utilized by Wi-Fi 5 (IEEE (Institute of Electrical and Electronics Engineers) 802.11ac), Wi-Fi 6 or Wi-Fi 6E (IEEE 802.11ax), Wi-Fi 7 (IEEE 802.11be)).

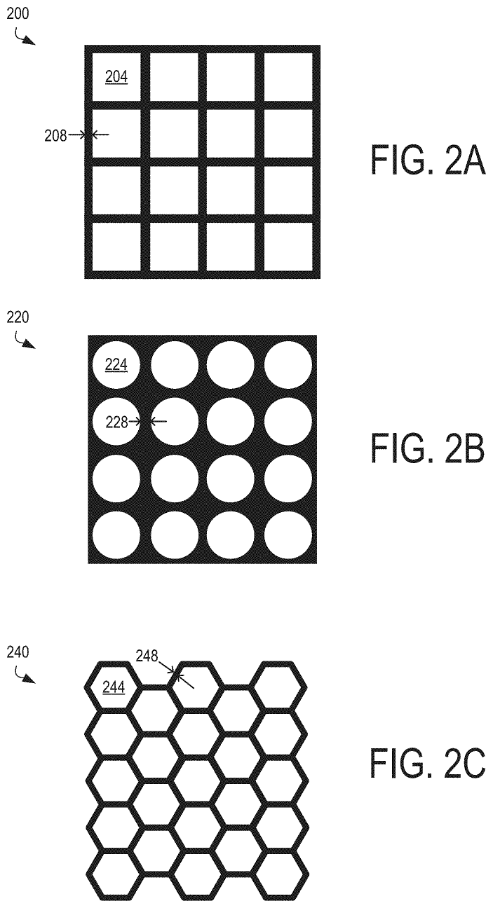

FIGS. 2A-2C illustrate example chassis ventilation hole patterns. FIG. 2A illustrates an array 200 of square ventilation holes 204, FIG. 2B illustrates an array 220 of circular ventilation holes 224, and FIG. 2C illustrates an array 240 of hexagonal ventilation holes 244. In some embodiments, the area of the ventilation holes (ventilation hole area) can be in the range of 30-40 mm². In some embodiments, the area of the ventilation holes is about 36 mm². Adjacent ventilation holes 204, 224, and 244 are separated by ventilation hole dividers 208, 228, and 248, respectively. In some embodiments, the dividers 208, 228, and 248 can have a thickness of 0.5-1.5 mm. In some embodiments, the dividers 208, 228, and 248 have a thickness of about 1.0 mm. In some embodiments, chassis sides can comprise ventilation holes having a shape different than square, circular, or hexagonal, such as another polygonal shape (e.g., triangular) or any other shape (such as cross patterns, which will be discussed in greater detail below).

The antenna and fan portions of a chassis side can have the same ventilation hole pattern, as shown in FIG. 1. In other embodiments, the antenna and fan portions can have different ventilation patterns. In other embodiments, an antenna or fan portion of a chassis side can comprise a ventilation hole pattern that varies within the antenna or fan portion.

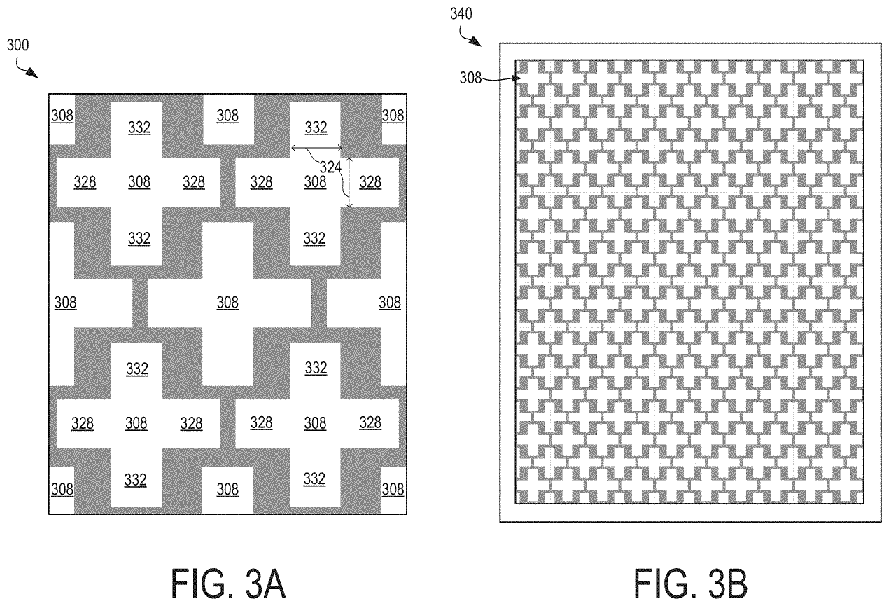

FIGS. 3A-3B illustrate first example cross pattern ventilation holes. The ventilation hole arrays 300 and 340 comprise overlapping negative cross pattern ventilation holes 308. The ventilation holes 308 overlap in the vertical and horizontal directions. The array 300 comprises five complete negative cross pattern ventilation holes 308 and the array 340 illustrated in FIG. 3B comprises a larger number of negative cross pattern ventilation holes 308. The negative cross pattern ventilation holes 308 comprise pairs of intersecting bar-shaped openings 328 and 332 to create cross-shaped openings. The bar-shaped openings 328 and 332 have a width 324. In some embodiments in which the ventilation holes are to provide EMI shielding for the Wi-Fi 6 GHz frequency band, the width 324 is about 3 mm and the negative cross pattern ventilation holes have a ventilation hole area of about 45 mm² (five 3 mm×3 mm openings). In other embodiments, the width 324 can be in the range of 2.5-4.0 mm. In still other embodiments, the width 336 can be less than 3 mm to provide shielding for antennas that are to transmit at a frequency greater than the Wi-Fi 6 GHz frequency band. The ventilation hole patterns illustrated in FIGS. 3A-3B have similar thermal performance as the ventilation hole patterns illustrated in FIGS. 2A-2C. Table 1 illustrates thermal simulation results of a desktop system operating at 125 W with circular (e.g., FIG. 2B), square (e.g., FIG. 2A), hexagonal (e.g., FIG. 2C) and overlapping negative cross pattern with 3 mm-wide bar-shaped opening features (e.g., FIG. 3A) ventilation holes. The average temperature of the air within the chassis (first row), average temperature of the air exhausted through the top vent in the chassis (second row), average temperature of the air exhausted through the bac, vent in the chassis (third row), and the average rise in temperature of the exhausted air from both ports over the room ambient temperature for various total chassis power levels (fourth through sixth rows) show similar thermal results for the various ventilation hole patterns.

TABLE 1

| | Circle | Square | Hexagonal | Cross |
|---|---|---|---|---|
| Average chassis temperature | 37.3 | 37.7 | 37.1 | 37.6 |
| (° C.) | | | | |
| Average temperature exhausted | 40.8 | 41.4 | 40.3 | 42.1 |
| through top vent (° C.) | | | | |
| Average temperature exhausted | 37.6 | 37.7 | 37.5 | 37.9 |
| through back vent (° C.) | | | | |
| Average temperature rise from | 3.8 | 4.2 | 3.7 | 4.1 |
| room ambient for total chassis | | | | |
| power = 162 W (° C.) | | | | |
| Average temperature rise from | 4.7 | 5.2 | 4.5 | 5.0 |
| room ambient for total chassis | | | | |
| power = 200 W (° C.) | | | | |
| Average temperature rise from | 7.1 | 7.8 | 6.8 | 7.5 |
| room ambient for total chassis | | | | |
| power = 300 W (° C.) | | | | |

3D electromagnetic simulations based on computational fluid dynamic models using Floquet excitation and boundary conditions indicate the negative cross pattern ventilation hole patterns illustrated in FIGS. 3A-3B provide EMI shielding effectiveness comparable to the ventilation hole patterns illustrated in FIGS. 2A-2C. The simulation results further indicate that the negative cross pattern ventilation holes illustrated in FIGS. 3A-3B have an EMI shielding effectiveness sensitivity to ventilation hole thickness similar to that of the ventilation hole patterns illustrated in FIGS. 2A-2C. Thus, an array of negative cross pattern ventilation holes, such as array 380, can be used in a fan portion of a chassis side.

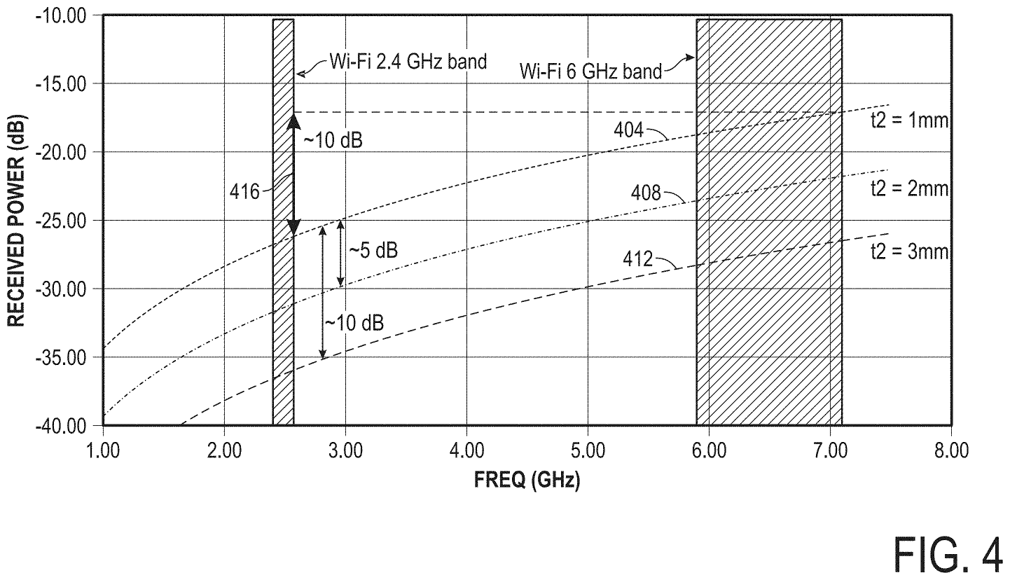

FIG. 4 is a chart illustrating EMI shielding dependency on ventilation hole thickness for a ventilation hole array comprising circular ventilation holes. The chart 400 illustrates the power level received on the external surface of a chassis side from an aggressor (e.g., a DDR memory module) located in the chassis interior, based on 3D electromagnetic simulations based on computational fluid dynamic models using Floquet modal excitations and boundary conditions for the periodic ventilation hole structures illustrated in FIGS. 2A-2C. The lower the received power level, the better the platform noise isolation. The chart 400 shows relative receptive power levels over a range of frequencies for circular ventilation holes arranged in the array pattern shown in FIG. 2B, having a ventilation hole area of 36 mm² and a ventilation hole spacing of 1 mm (e.g., divider 228). Curves 404, 408, and 412 correspond to circular ventilation hole thicknesses (thickness t2 with reference to FIG. 1B) of 1, 2, and 3 mm, respectively. The range of frequencies covers the Wi-Fi 2.4 GHz (2.40-2.48 GHz), 5 GHz (5.16-5.89 GHz), and 6 GHz (5.925-7.125 GHz) frequency bands, although only the Wi-Fi 2.4 and 6 GHz bands are labeled.

Chart 400 indicates that increasing the ventilation hole thickness from 1 mm to 2 mm increases the EMI shielding effectiveness by about 5 dB and increasing it further from 2 mm to 3 mm increases the EMI shielding effectiveness by about another 5 dB. Thus, chart 400 indicates that increasing the thickness of circular ventilation holes from 1 mm to 3 mm improves the shielding effectiveness by about 10 dB (increasing the noise isolation by 90%), which is about the increase in platform noise between the upper ends of the Wi-Fi 2.4 GHz and 6 GHz frequency bands (as indicated by difference 416) in the chart 400. That is, computing systems comprising DDR5/LPDDR5 memories (or other components) operating at 5-7 GT/s would benefit from comprising a metal chassis that can provide 10 dB improved EMI shielding effectiveness relative to metal chassis comprising components that operate at frequencies at or around the 2.4 GHz Wi-Fi frequency band. As mentioned earlier, simulation results indicate that increasing the ventilation hole thickness from 1 mm to 3 mm does not substantially degrade the venting of heated air from the chassis interior. Simulation results for the square and hexagonal ventilation hole patterns illustrated in FIGS. 2A and 2C and having a ventilation hole area of 36 mm² and spacing of 1 mm indicate similar 5 and 10 dB improvements in EMI shielding effectiveness resulting from increasing the ventilation hole thickness from 1 mm to 2 mm and 1 mm to 3 mm, respectively.

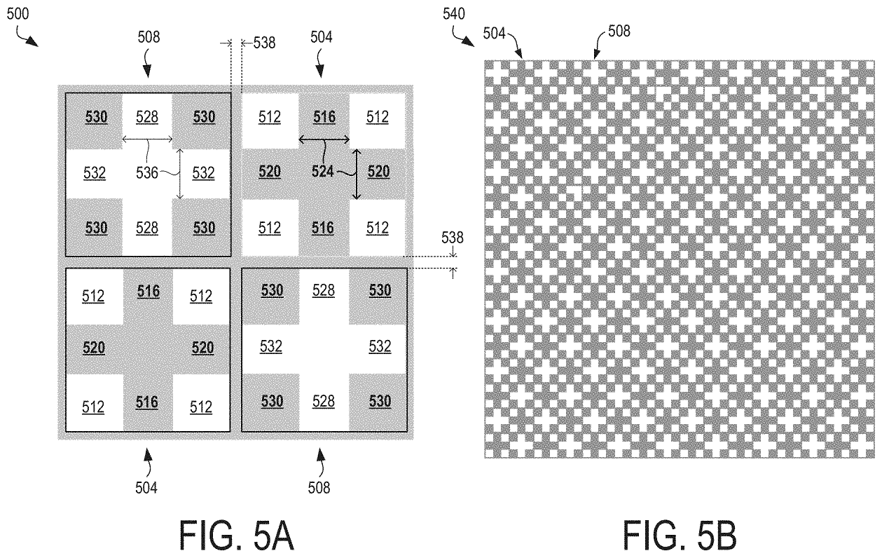

FIGS. 5A-5B illustrate second example cross pattern ventilation holes. FIG. 5A illustrates a 2×2 array 500 in which positive cross pattern ventilation holes 504 and negative cross pattern ventilation holes 508 are arranged in an alternating pattern. The positive cross pattern ventilation holes 504 and the negative cross pattern ventilation holes 508 alternate horizontally and vertically. The array 500 can be considered a unit cell that is repeated to create a larger array of alternating positive and negative cross pattern ventilation holes, such as array 540 illustrated in FIG. 5B. The grey and white regions of the illustrated ventilation holes indicate the presence and absence of chassis side material (e.g., metal), respectively. Positive cross pattern ventilation holes 504 comprise four openings 512 and a pair of intersecting bars 516 and 520 of chassis side material that forms a cross pattern. The bars 516 and 520 have a width 524. Negative cross pattern ventilation holes 508 comprise four corners 530 of chassis side material and a pair of intersecting bar-shaped openings 528 and 532 that form a cross-shaped opening. The bar-shaped openings 528 and 532 have a width 536. In some embodiments, widths 524 and 536 are substantially the same. In some embodiments, the widths 524 and 536 are about 3 mm, with the positive cross pattern ventilation holes having a hole area of about 36 mm² (four 3 mm×3 mm openings) and the negative cross pattern ventilation holes having a hole area of about 45 mm² (five 3 mm×3 mm openings). Adjacent ventilation holes have a divider 538 between them. In some embodiments, the width of the divider 538 is about 1 mm. FIG. 5B illustrates a 16×16 array 540 of ventilation holes comprising positive cross pattern ventilation holes 504 alternating horizontally and vertically with negative positive cross pattern holes 508.

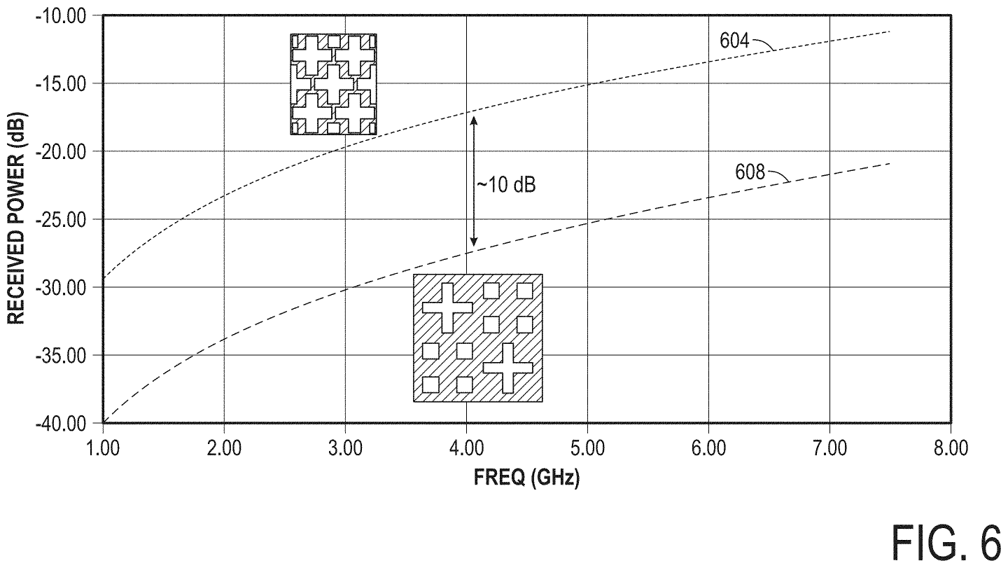

FIG. 6 is a chart illustrating EMI shielding effectiveness for the ventilation hole patterns illustrated in FIGS. 3A-3B and FIGS. 5A-5B. Similar to chart 400, chart 600 illustrates the power levels received on the external surface of a chassis side from an aggressor (e.g., a DDR memory module) located in the chassis interior, based on 3D electromagnetic simulations based on computational fluid dynamic models using Floquet modal excitations and boundary conditions for the periodic ventilation hole structures illustrated in FIGS. 3A-3B (curve 604) and FIGS. 5A-5B (curve 608), for the same ventilation hole thickness. The simulation results indicate that alternating positive and negative cross pattern ventilation holes as illustrated in FIGS. 5A-5B can provide a 10 dB improvement in the EMI shielding effectiveness over overlapping negative cross pattern ventilation holes illustrated in FIGS. 3A-3B, for the same ventilation hole thickness.

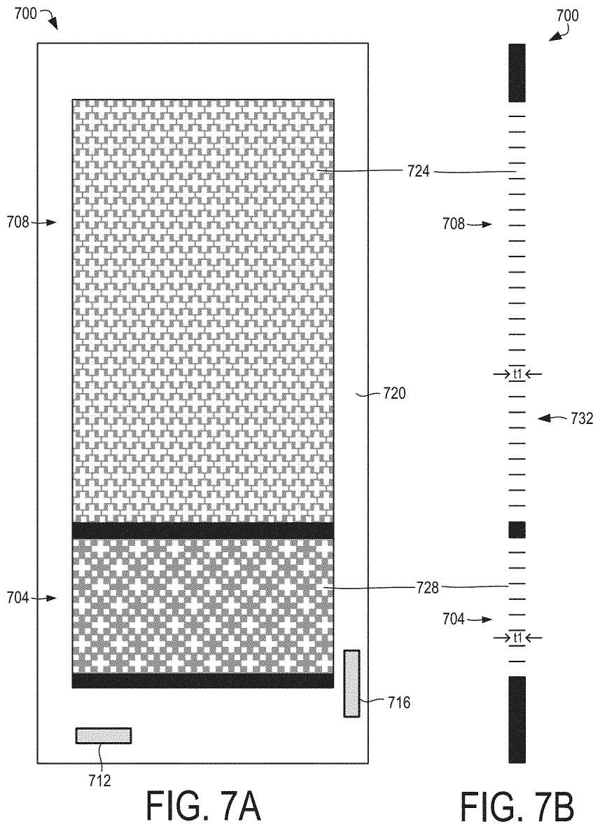

FIGS. 7A and 7B illustrate front and side views, respectively, of a second example chassis side. Chassis side 700 comprises a unitary component 732. An antenna portion 704 comprises a first portion of the unitary component 732 and a fan portion 708 comprises a second portion of the unitary component 732. Antennas 712 and 716 are located on an external surface 720 of the chassis side 700. The fan portion 704 comprises ventilation holes 724 and the antenna portion 704 comprises ventilation holes 728. The antenna portion 704 is a portion of the chassis side 700 that is located closer to the antennas 712 and 716 than the fan portion 708.

The ventilation holes 728 comprise positive and negative cross pattern ventilation holes that alternate horizontally and vertically, and the ventilation holes 724 comprise overlapping negative cross pattern ventilation holes. By utilizing alternating positive and negative cross pattern ventilation holes in the antenna portion, the ventilation holes 724 and 728 can have the same thickness t1. A chassis side having the same ventilation hole thickness in the antenna and fan portions can be less expensive and lighter than a chassis having thicker ventilation holes in the antenna portion. The antenna portion 704 of the chassis side 700 can extend from an antenna to a distance at which the reception power is a threshold amount lower (e.g., 30 dB) than at the antenna. In some embodiments, the antenna portion 704 of the chassis side 700 extends at least 5 cm from antennas 712 and 716.

Although the fan portion 708 illustrated in FIG. 7A comprises overlapping negative cross pattern ventilation holes, in other embodiments, the fan portion 708 can comprise any of the ventilation hole patterns illustrated in FIGS. 2A-2C, FIG. 3A, or ventilation holes having other shapes (e.g., triangular), or any other ventilation hole pattern that provides a desired level of heated air venting.

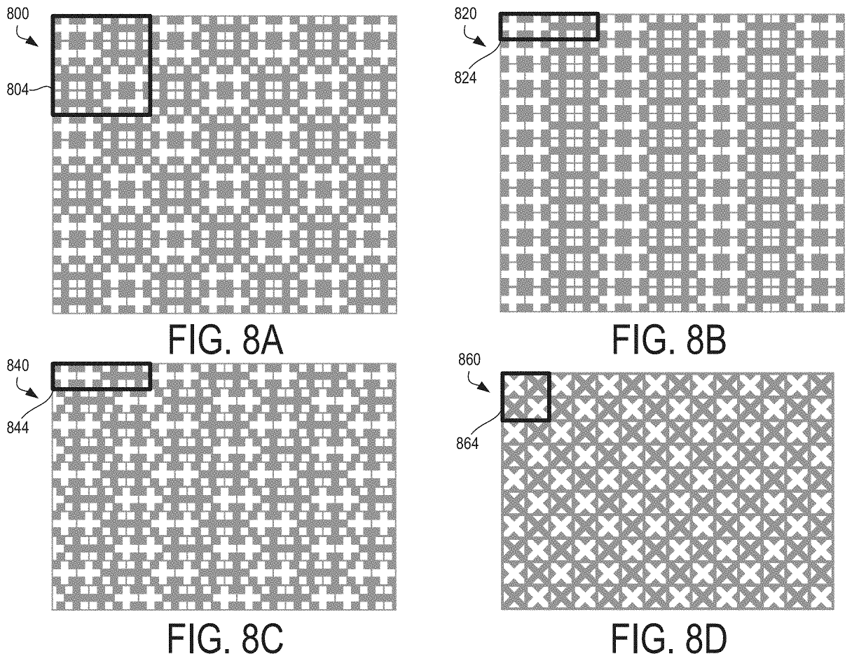

FIGS. 8A-8D illustrate additional example ventilation hole patterns that can be used in an antenna portion of a chassis side. FIG. 8A illustrates an array 800 of alternating positive and negative cross pattern ventilation holes with a 4×4 unit cell 804 comprising alternating 2×2 arrays of positive and negative cross pattern ventilation holes. In other embodiments, the unit cell can comprise four N×N arrays of positive and negative cross pattern ventilation holes, the N×N arrays arranged in an alternating pattern. FIG. 8B illustrates an array 820 of alternating positive and negative cross pattern ventilation holes with a 1×4 unit cell 824 comprising two negative cross pattern ventilation holes adjacent to two positive cross pattern ventilation holes. Thus, the array 820 comprises rows having the same ventilation hole pattern. In other embodiments, a ventilation hole array comprises a repeating 4×1 unit cell comprising two negative cross pattern ventilation holes adjacent to two positive cross patterns cells and the array comprises columns having the same ventilation hole pattern. FIG. 8C illustrates an array 840 of ventilation holes with alternating positive and negative cross pattern ventilation holes with a 1×4 unit cell 844 comprising two negative cross pattern ventilation holes adjacent to two positive cross pattern ventilation holes where the unit cell 844 is shifted by one-half the width of a ventilation hole in adjacent rows. In other embodiments, the ventilation holes in adjacent rows is offset by a different amount than one-half the width of a ventilation hole. In other embodiments, the unit cell is a 4×1 array comprising two negative cross pattern ventilation holes adjacent to two positive cross pattern ventilation holes and the ventilation holes in adjacent columns are offset by one-half the width of a ventilation hole or another amount. FIG. 8D illustrates an array 860 of ventilation holes with alternating positive and negative cross pattern ventilation holes with a 2×2 unit cell 864 comprising alternating negative and positive cross pattern ventilation holes in the horizontal and vertical directions, with cross patterns rotated 45 degrees relative to the ventilation hole patterns of FIGS. 3A, 5A, and 8A-8C. The positive and negative cross pattern ventilation holes can be rotated by an angle other than 45 degrees in other embodiments relative to the ventilation hole patterns of FIGS. 3A, 5A, and 8A-8C or relative to a feature of a chassis side, such as an edge of a chassis side. In some embodiments, the positive and negative cross pattern ventilation holes can be rotated by an amount other than 45 degrees. Other alternating positive and negative cross pattern ventilation hole arrangements that provide improved EMI shielding without having to increase the ventilation hole thickness in an antenna portion are possible.

The metal chassis described herein can be implemented in any of a variety of computing systems, such as desktop computers, servers, workstations, stationary gaming consoles, set-top boxes, smart televisions, rack-level computing solutions (e.g., blade, tray, or sled computing systems)), or any other computing system in which heated air is vented from the interior of the computing system using ventilation holes and in which antenna are mounted on an external surface of a chassis side comprising the ventilation holes. As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

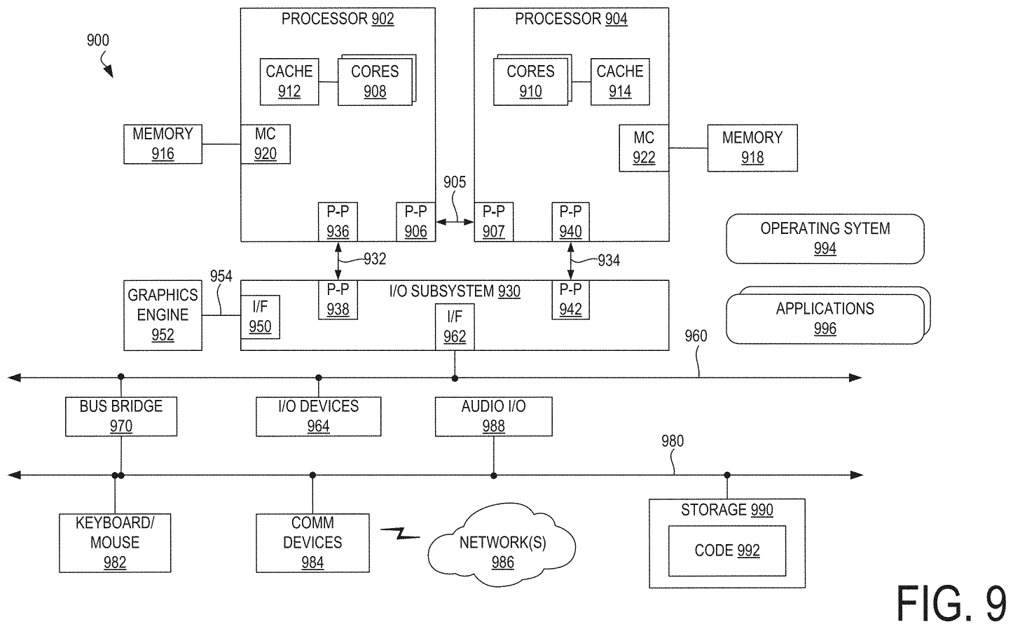

FIG. 9 is a block diagram of a second example computing system in which technologies described herein may be implemented. Generally, components shown in FIG. 9 can communicate with other shown components, although not all connections are shown, for ease of illustration. The computing system 900 is a multiprocessor system comprising a first processor unit 902 and a second processor unit 904 comprising point-to-point (P-P) interconnects. A point-to-point (P-P) interface 906 of the processor unit 902 is coupled to a point-to-point interface 907 of the processor unit 904 via a point-to-point interconnection 905. It is to be understood that any or all of the point-to-point interconnects illustrated in FIG. 9 can be alternatively implemented as a multi-drop bus, and that any or all buses illustrated in FIG. 9 could be replaced by point-to-point interconnects.

The processor units 902 and 904 comprise multiple processor cores. Processor unit 902 comprises processor cores 908 and processor unit 904 comprises processor cores 910. Processor cores 908 and 910 can execute computer-executable instructions in a manner similar to that discussed below in connection with FIG. 8, or other manners.

Processor units 902 and 904 further comprise cache memories 912 and 914, respectively. The cache memories 912 and 914 can store data (e.g., instructions) utilized by one or more components of the processor units 902 and 904, such as the processor cores 908 and 910. The cache memories 912 and 914 can be part of a memory hierarchy for the computing system 900. For example, the cache memories 912 can locally store data that is also stored in a memory 916 to allow for faster access to the data by the processor unit 902. In some embodiments, the cache memories 912 and 914 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 900 is shown with two processor units, the computing system 900 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 900 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 902 and 904 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 902 and 904 further comprise memory controller logic (MC) 920 and 922. As shown in FIG. 9, MCs 920 and 922 control memories 916 and 918 coupled to the processor units 902 and 904, respectively. The memories 916 and 918 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 920 and 922 are illustrated as being integrated into the processor units 902 and 904, in alternative embodiments, the MCs can be external to a processor unit.

Processor units 902 and 904 are coupled to an Input/Output (I/O) subsystem 930 via point-to-point interconnections 932 and 936. The point-to-point interconnection 932 connects a point-to-point interface 936 of the processor unit 902 with a point-to-point interface 938 of the I/O subsystem 930, and the point-to-point interconnection 934 connects a point-to-point interface 940 of the processor unit 904 with a point-to-point interface 942 of the I/O subsystem 930. Input/Output subsystem 930 further includes an interface 950 to couple the I/O subsystem 930 to a graphics engine 952. The I/O subsystem 930 and the graphics engine 952 are coupled via a bus 954.

The Input/Output subsystem 930 is further coupled to a first bus 960 via an interface 962. The first bus 960 can be a Peripheral Component Interconnect Express (PCIe) bus or any other type of bus. Various I/O devices 964 can be coupled to the first bus 960. A bus bridge 970 can couple the first bus 960 to a second bus 980. In some embodiments, the second bus 980 can be a low pin count (LPC) bus. Various devices can be coupled to the second bus 980 including, for example, a keyboard/mouse 982, audio I/O devices 988, and a storage device 990, such as a hard disk drive, solid-state drive, or another storage device for storing computer-executable instructions (code) 992 or data. The code 992 can comprise computer-executable instructions for performing methods described herein. Additional components that can be coupled to the second bus 980 include communication device(s) 984, which can provide for communication between the computing system 900 and one or more wired or wireless networks 986 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 902.11 standard and its supplements).

In embodiments where the communication devices 984 support wireless communication, the communication devices 984 can comprise wireless communication components coupled to one or more antennas to support communication between the computing system 900 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 900 can comprise removable memory such as flash memory cards (e.g., SD (Secure Digital) cards), memory sticks, Subscriber Identity Module (SIM) cards). The memory in system 900 (including caches 912 and 914, memories 916 and 918, and storage device 990) can store data and/or computer-executable instructions for executing an operating system 994 and application programs 996. Example data includes web pages, text messages, images, sound files, and video data be sent to and/or received from one or more network servers or other devices by the system 900 via the one or more wired or wireless networks 986, or for use by the system 900. The system 900 can also have access to external memory or storage (not shown) such as external hard drives or cloud-based storage.

The operating system 994 can control the allocation and usage of the components illustrated in FIG. 9 and support the one or more application programs 996. The application programs 996 can include common computing system applications (e.g., email applications, calendars, contact managers, web browsers, messaging applications) as well as other computing applications.

The computing system 900 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. Other possible input and output devices include piezoelectric and other haptic I/O devices. Any of the input or output devices can be internal to, external to, or removably attachable with the system 900. External input and output devices can communicate with the system 900 via wired or wireless connections.

The system 900 can further include at least one input/output port comprising physical connectors (e.g., USB, IEEE 1394 (FireWire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 900 can further comprise one or more additional antennas coupled to one or more additional receivers, transmitters, and/or transceivers to enable additional functions.

It is to be understood that FIG. 9 illustrates only one example computing system architecture. Computing systems based on alternative architectures can be used to implement technologies described herein. For example, instead of the processors 902 and 904 and the graphics engine 952 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 9. Moreover, the illustrated components in FIG. 9 are not required or all-inclusive, as shown components can be removed and other components added in alternative embodiments.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising: an antenna; and a chassis comprising a chassis side, the chassis side comprising a first portion comprising a first plurality of ventilation holes and a second portion comprising a second plurality of ventilation holes, the first plurality of ventilation holes having a first thickness, the second plurality of ventilation holes having a second thickness, the first thickness greater than the second thickness, the antenna located on an external surface of the chassis side, the first portion located closer to the antenna than the second portion.

Example 2 comprises the apparatus of example 1, wherein the first portion of the chassis side is a first portion of a unitary component and the second portion of the chassis side is a second portion of the unitary component.

Example 3 comprises the apparatus of example 1, wherein the chassis side further comprises: a unitary component, the first portion of the chassis side comprising a first portion of the unitary component, the second portion of the chassis side comprising a second portion of the unitary component; and one or more ventilation brackets located on an internal surface of the unitary component and/or an external surface of the unitary component, the plurality of first ventilation holes extending through the unitary component and the one or more ventilation brackets, the first thickness being a thickness of the unitary component plus a thickness of the one or more ventilation brackets.

Example 4 comprises the apparatus of any one of examples 1-3, wherein the plurality of first ventilation holes comprises overlapping negative cross pattern ventilation holes.

Example 5 comprises the apparatus of any one of examples 1-4, wherein the first thickness is in the range of 2-4 mm.

Example 6 comprises the apparatus of any one of examples 1-4, wherein the first thickness is about 3 mm.

Example 7 comprises the apparatus of any one of examples 1-6, wherein individual ventilation holes of the first plurality of ventilation holes and individual ventilation holes of the second plurality of ventilation holes have substantially the same shape.

Example 8 comprises the apparatus of any one of examples 1-7, wherein individual of the first plurality of ventilation holes are circular.

Example 9 comprises the apparatus of any one of examples 1-7, wherein individual of the first plurality of ventilation holes are hexagonal.

Example 10 comprises the apparatus of any one of examples 1-7, wherein individual of the first plurality of ventilation holes are square.

Example 11 comprises the apparatus of any one of examples 1-7, wherein individual of the first plurality of ventilation holes are polygonal.

Example 12 comprises the apparatus of any one of examples 1-7, wherein individual of the first plurality of ventilation holes are negative cross pattern ventilation holes.

Example 13 comprises the apparatus of any one of examples 1-12, wherein individual ventilation holes of the first plurality of ventilation holes and individual ventilation holes of the second plurality of ventilation holes have substantially the same ventilation hole area.

Example 14 comprises the apparatus of any one of examples 1-13, wherein individual of the first plurality of ventilation holes have a ventilation hole area of about 36 mm².

Example 15 comprises the apparatus of any one of examples 1-13, wherein individual of the first plurality of ventilation holes have a ventilation hole area in the range of 30-44 mm².

Example 16 comprises the apparatus of any one of examples 1-15, wherein the first plurality of ventilation holes and the second plurality of ventilation holes have substantially the same ventilation hole pattern.

Example 17 is an apparatus, comprising: an antenna; and a chassis comprising a chassis side, the chassis side comprising a first portion comprising a first plurality of ventilation holes and a second portion comprising a second plurality of ventilation holes, the first plurality of ventilation holes having a first thickness, the second plurality of ventilation holes having a second thickness, the first thickness being substantially the same as the second thickness, the antenna located on an external surface of the chassis side, the first plurality of ventilation holes comprising a plurality of positive cross pattern ventilation holes and a plurality of negative cross pattern ventilation holes, the first portion located closer to the antenna than the second portion.

Example 18 comprises the apparatus of example 17, wherein individual of the positive cross pattern ventilation holes comprise a pair of intersecting bars and individual of the negative cross pattern ventilation holes comprise a pair of intersecting bar-shaped openings.

Example 19 comprises the apparatus of example 18, wherein the bars of the positive cross pattern ventilation holes and the bar-shaped openings of the negative cross pattern ventilation holes have a width of about 3 mm.

Example 20 comprises the apparatus of any one of examples 17-19, wherein the positive cross pattern ventilation holes and the negative cross pattern ventilation holes are arranged in an alternating pattern.

Example 21 comprises the apparatus of any one of examples 17-19, wherein the positive cross pattern ventilation holes and the negative cross pattern ventilation holes are arranged in a pattern that alternates between positive cross pattern ventilation holes and negative cross pattern ventilation holes horizontally and vertically.

Example 22 comprises the apparatus of any one of examples 17-19, wherein the positive cross pattern ventilation holes and the negative cross pattern ventilation holes are arranged in an array that alternates between an N×N array of positive cross pattern ventilation holes and an N×N array of negative cross pattern ventilation holes.

Example 23 comprises the apparatus of any one of examples 17-21, wherein at least one of the positive cross pattern ventilation holes and at least one of the negative cross pattern ventilation holes are rotated with respect to an edge of the chassis side.

Example 24 comprises the apparatus of any one of examples 17-23, further comprising a divider having a thickness of about 1 mm between adjacent positive cross pattern ventilation holes and between negative cross pattern ventilation holes.

Example 25 comprises the apparatus of any one of examples 17-24, wherein a ventilation hole area of individual of the positive cross pattern ventilation is about 36 mm².

Example 26 comprises the apparatus of any one of examples 17-24, wherein a ventilation hole area of individual of the negative cross pattern ventilation is about 45 mm².

Example 27 comprises the apparatus of any one of examples 17-26, wherein individual of the second plurality of ventilation holes have a substantially similar shape.

Example 28 comprises the apparatus of any one of examples 17-27, wherein individual of the second plurality of ventilation holes are circular.

Example 29 comprises the apparatus of any one of examples 17-27, wherein individual of the second plurality of ventilation holes are hexagonal.

Example 30 comprises the apparatus of any one of examples 17-27, wherein individual of the second plurality of ventilation holes are square.

Example 31 comprises the apparatus of any one of examples 17-27, wherein individual of the second plurality of ventilation holes are polygonal.

Example 32 comprises the apparatus of any one of examples 17-27, wherein individual of the second plurality of ventilation holes are negative cross pattern ventilation holes.

Example 33 comprises the apparatus of any one of examples 17-27, wherein the second plurality of ventilation holes comprise overlapping negative cross pattern ventilation holes.

Example 34 comprises the apparatus of any one of examples 1-33, wherein the antenna is to produce electromagnetic waves having a frequency less than 10 GHz.

Example 35 comprises the apparatus of any one of examples 1-33, wherein the antenna is to produce electromagnetic waves in the Wi-Fi 2 GHz frequency band.

Example 36 comprises the apparatus of any one of examples 1-33, wherein the antenna is to produce electromagnetic waves in the Wi-Fi 6 GHz frequency band.

Example 37 comprises the apparatus of any one of examples 1-35 wherein the second plurality of ventilation holes is at least 5 cm away from the antenna.

Example 38 comprises the apparatus of any one of examples 1-37 wherein the first plurality of ventilation holes are within 5 cm of the antenna.

Example 39 comprises the apparatus of any one of examples 1-38, further comprising one or more integrated circuit components located in the chassis.

Example 40 comprises the apparatus of any one of examples 1-39, further comprising a fan located in the chassis.

Example 41 is a computing system comprising: an antenna; an integrated circuit component; a shielding means to shield the antenna from electromagnetic noise to be generated by the integrated circuit component when the integrated circuit component is in operation and to vent air heated by the integrated circuit component out of the computing system; and a venting means to vent air heated by the integrated circuit component out of the computing system, the shielding means located closer to the antenna than the venting means.

Example 42 comprises the computing system of example 41, further comprising a fan.

1. An apparatus, comprising:
an antenna; and
a chassis comprising a chassis side, the chassis side comprising a first portion comprising a first plurality of ventilation holes and a second portion comprising a second plurality of ventilation holes, the first plurality of ventilation holes having a first thickness, the second plurality of ventilation holes having a second thickness, the first thickness greater than the second thickness, the antenna located on an external surface of the chassis side, the first portion located closer to the antenna than the second portion.

2. The apparatus of claim 1, wherein the first portion of the chassis side is a first portion of a unitary component and the second portion of the chassis side is a second portion of the unitary component.

3. The apparatus of claim 1, wherein the chassis side further comprises:
a unitary component, the first portion of the chassis side comprising a first portion of the unitary component, the second portion of the chassis side comprising a second portion of the unitary component; and
one or more ventilation brackets located on an internal surface of the unitary component and/or an external surface of the unitary component, the plurality of first ventilation holes extending through the unitary component and the one or more ventilation brackets, the first thickness being a thickness of the unitary component plus a thickness of the one or more ventilation brackets.

4. The apparatus of claim 1, wherein the plurality of first ventilation holes comprises overlapping negative cross pattern ventilation holes.

5. The apparatus of claim 1, wherein the first thickness is about 3 mm.

6. The apparatus of claim 1, wherein individual ventilation holes of the first plurality of ventilation holes and individual ventilation holes of the second plurality of ventilation holes have substantially the same shape.

7. The apparatus of claim 1, wherein individual of the first plurality of ventilation holes are negative cross pattern ventilation holes.

8. The apparatus of claim 1, wherein individual ventilation holes of the first plurality of ventilation holes and individual ventilation holes of the second plurality of ventilation holes have substantially the same ventilation hole area.

9. The apparatus of claim 1, wherein the antenna is to produce electromagnetic waves in the Wi-Fi 2 GHz or the Wi-Fi 6 GHz frequency band.

10. The apparatus of claim 1, wherein the first plurality of ventilation holes are within 5 cm of the antenna.

11. The apparatus of claim 1, further comprising one or more integrated circuit components located in the chassis.

12. An apparatus, comprising:
an antenna; and
a chassis comprising a chassis side, the chassis side comprising a first portion comprising a first plurality of ventilation holes and a second portion comprising a second plurality of ventilation holes, the first plurality of ventilation holes having a first thickness, the second plurality of ventilation holes having a second thickness, the first thickness being substantially the same as the second thickness, the antenna located on an external surface of the chassis side, the first plurality of ventilation holes comprising a plurality of positive cross pattern ventilation holes and a plurality of negative cross pattern ventilation holes, the first portion located closer to the antenna than the second portion.

13. The apparatus of claim 12, wherein individual of the positive cross pattern ventilation holes comprise a pair of intersecting bars and individual of the negative cross pattern ventilation holes comprise a pair of intersecting bar-shaped openings.

14. The apparatus of claim 13, wherein the bars of the positive cross pattern ventilation holes and the bar-shaped openings of the negative cross pattern ventilation holes have a width of about 3 mm.

15. The apparatus of claim 12, wherein the positive cross pattern ventilation holes and the negative cross pattern ventilation holes are arranged in an alternating pattern.

16. The apparatus of claim 12, wherein the positive cross pattern ventilation holes and the negative cross pattern ventilation holes are arranged in a pattern that alternates between positive cross pattern ventilation holes and negative cross pattern ventilation holes horizontally and vertically.

17. The apparatus of claim 12, wherein the positive cross pattern ventilation holes and the negative cross pattern ventilation holes are arranged in an array that alternates between an N×N array of positive cross pattern ventilation holes and an N×N array of negative cross pattern ventilation holes.

18. The apparatus of claim 12, wherein at least one of the positive cross pattern ventilation holes and at least one of the negative cross pattern ventilation holes are rotated with respect to an edge of the chassis side.

19. The apparatus of claim 12, wherein individual of the second plurality of ventilation holes have a substantially similar shape.

20. The apparatus of claim 12, wherein individual of the second plurality of ventilation holes are negative cross pattern ventilation holes.

21. The apparatus of claim 12, wherein the antenna is to produce electromagnetic waves in the Wi-Fi 2 GHz or the Wi-Fi 6 GHz frequency band.

22. The apparatus of claim 12, wherein the second plurality of ventilation holes is at least 5 cm away from the antenna.

23. The apparatus of claim 12, further comprising one or more integrated circuit components located in the chassis.

24. A computing system comprising:
an antenna;
an integrated circuit component;
a shielding means to shield the antenna from electromagnetic noise to be generated by the integrated circuit component when the integrated circuit component is in operation and to vent air heated by the integrated circuit component out of the computing system; and
a venting means to vent air heated by the integrated circuit component out of the computing system, the shielding means located closer to the antenna than the venting means.

25. The computing system of claim 24, further comprising a fan.
